(19) United States
(12) Patent Application Publication
(10) Pub. No.: US 2025/0241060 A1
(43) Pub. Date: Jul. 24, 2025

(54) INTEGRATED CIRCUIT DEVICES HAVING ENHANCED POWER DELIVERY NETWORKS THEREIN

(71) Applicant: Samsung Electronics Co., Ltd., Suwon-si (KR)

(72) Inventors: Seowoo Nam, Suwon-si (KR); Heonjong Shin, Suwon-si (KR); Sanghee Lee, Suwon-si (KR)

(21) Appl. No.: 18/796,633

(22) Filed: Aug. 7, 2024

(30) Foreign Application Priority Data
Jan. 19, 2024 (KR) 10-2024-0008943

(51) Int. Cl. H01L 27/092; H01L 23/528; H01L 29/06; H01L 29/417; H01L 29/423; H01L 29/45; H01L 29/775; H01L 29/786

(52) U.S. Cl. CPC H10D 84/856; H01L 23/5286; H10D 62/116; H10D 64/254; H10D 30/43; H10D 30/6735; H10D 30/6757; H10D 62/121; H10D 64/62

(57) ABSTRACT

An integrated circuit device includes: a substrate, a power delivery network layer including a lower interconnection line, on a bottom surface of the substrate, source/drain patterns including horizontally spaced-apart first and second patterns, on the substrate, a backside conductive structure that penetrates the substrate and electrically connects the first pattern to the power delivery network layer, and a lower insulating pattern extending below the second pattern, and in contact with a portion of the lower interconnection line.

### REFERENCE TO PRIORITY APPLICATION

This U.S. patent application claims priority under 35 U.S.C. § 119 to Korean Patent Application No. 10-2024-0008943, filed Jan. 19, 2024, the disclosure of which is hereby incorporated by reference.

### BACKGROUND OF THE INVENTION

The present disclosure relates to integrated circuit devices and, more particularly, to integrated circuit devices having highly integrated field effect transistors therein and methods of forming same.

An integrated circuit device includes an integrated circuit consisting of metal-oxide-semiconductor field-effect transistors (MOSFETs). To meet an increasing demand for an integrated circuit device with a small pattern size and a reduced design rule, MOSFETs are being aggressively scaled down. The scale-down of MOSFETs may lead to deterioration in operational properties of the integrated circuit devices. A variety of studies are being conducted to overcome technical limitations associated with the scale-down of integrated circuit devices and to realize higher performance therein.

### SUMMARY

An embodiment of the inventive concept provides an integrated circuit device with improved electrical characteristics and improved reliability.

According to an embodiment of the inventive concept, an integrated circuit device may include a substrate, a power delivery network layer with a lower interconnection line, on a bottom surface of the substrate, and source/drain patterns, which include first and second spaced apart patterns. A backside conductive structure is provided to penetrate the substrate and to electrically connect the first pattern to the power delivery network layer, and a lower insulating pattern is provided below the second pattern. In some embodiments, the lower insulating pattern may be in contact with a portion of the lower interconnection line.

According to an embodiment of the inventive concept, an integrated circuit device may include a substrate, a power delivery network layer on a bottom surface of the substrate, and source/drain patterns including first and second spaced-apart patterns on the substrate. A channel pattern is provided on a side surface of at least one of the first and second patterns, and includes a plurality of semiconductor patterns, which are vertically stacked to be spaced apart from each other. A gate electrode is provided between the semiconductor patterns, and a backside active contact is provided to penetrate the substrate and to electrically connect the first pattern to the power delivery network layer. A lower insulating pattern may also be provided below the second pattern, and an uppermost surface of the lower insulating pattern may be located at a level that is lower than or equal to an uppermost surface of the backside active contact.

According to an embodiment of the inventive concept, a semiconductor device may include a substrate, and a power delivery network layer including a lower interconnection line, on a bottom surface of a substrate. Source/drain patterns, which include first and second horizontally spaced apart patterns, may be provided along with a channel pattern, which extends on a side surface of the source/drain pattern(s) and includes a stack of spaced-apart semiconductor patterns. A gate electrode is provided, which extends between the semiconductor patterns. The gate electrode includes a first inner electrode, a second inner electrode, and a third inner electrode, which extend between adjacent ones of the semiconductor patterns, and an outer electrode, which is provided on the uppermost one of the semiconductor patterns. A gate insulating pattern is provided on the gate electrode, and a gate capping pattern is provided on a top surface of the outer electrode. A first interlayer insulating layer is provided on the source/drain patterns, a second interlayer insulating layer is provided on the first interlayer insulating layer and the gate capping pattern, a third interlayer insulating layer is provided on the second interlayer insulating layer and includes metal patterns and vias. An active contact is provided to penetrate the first and second interlayer insulating layers and to electrically connect the second pattern of the source/drain pattern to the metal pattern. A backside conductive structure is provided that penetrates the substrate and electrically connects the first pattern of the source/drain pattern to the power delivery network layer. A lower insulating pattern is provided that extends below the second pattern. A bottom surface of the lower insulating pattern and a bottom surface of the backside conductive structure may be substantially coplanar with each other, and a top surface of the lower insulating pattern may be located at a level that is lower than (or equal to) a top surface of the backside conductive structure.

### BRIEF DESCRIPTION OF THE DRAWINGS

FIG. 1 is a plan layout view illustrating an integrated circuit device according to an embodiment of the inventive concept.

FIGS. 2A to 2E are sectional views taken along lines A-A′, B-B′, C-C′, D-D′, and E-E′, respectively, of FIG. 1.

FIG. 3 is a sectional view illustrating another example of the integrated circuit device of FIG. 2A.

FIGS. 4A to 11B are diagrams illustrating methods of fabricating an integrated circuit device, according to an embodiment of the inventive concept.

### DETAILED DESCRIPTION OF EMBODIMENTS

Example embodiments of the inventive concepts will now be described more fully with reference to the accompanying drawings, in which example embodiments are shown. Like reference numerals in the drawings denote like elements, and thus their description will be omitted.

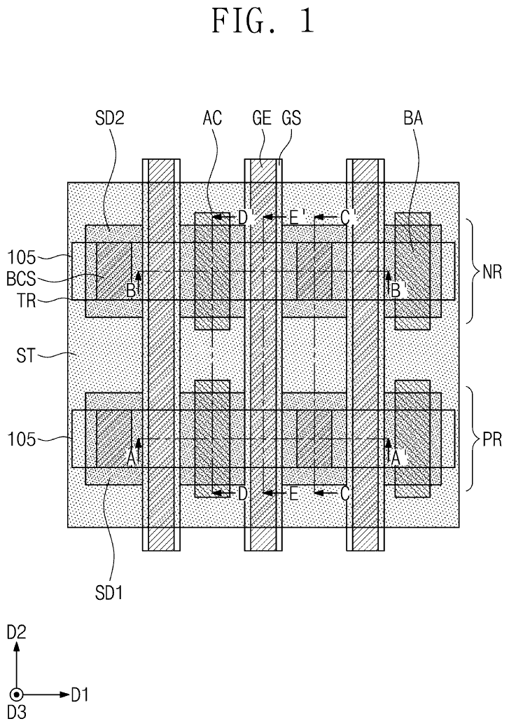

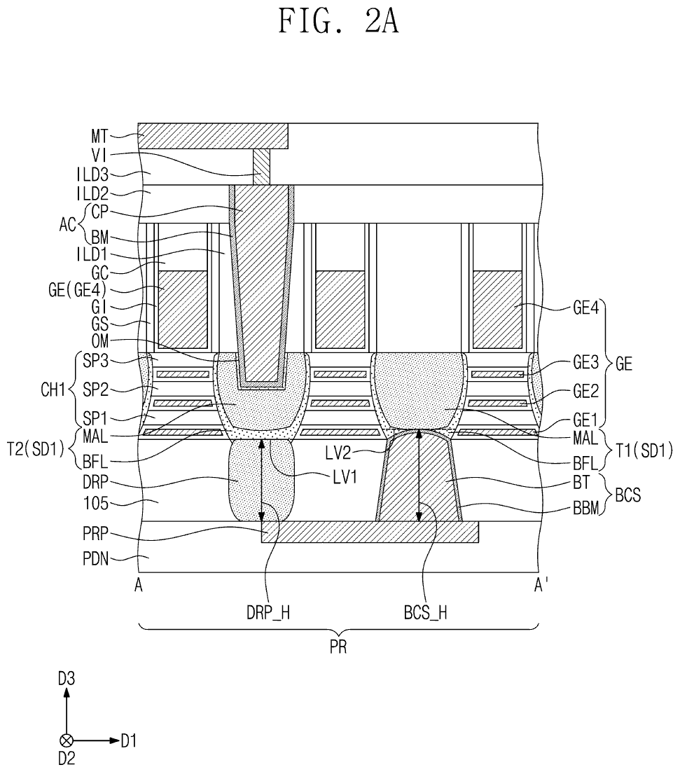

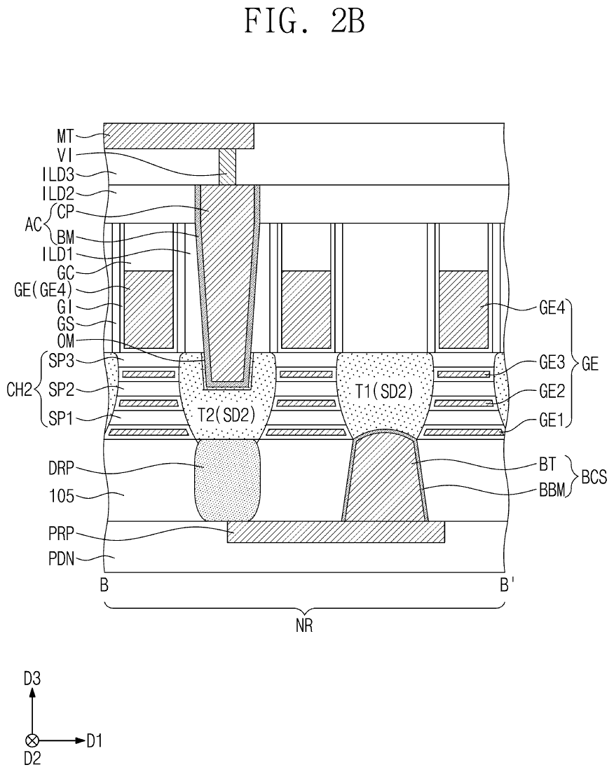

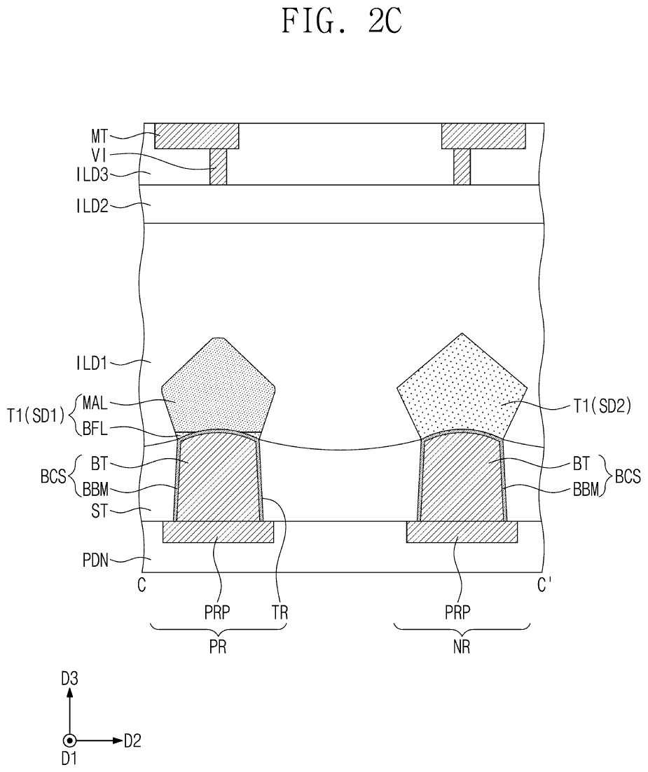

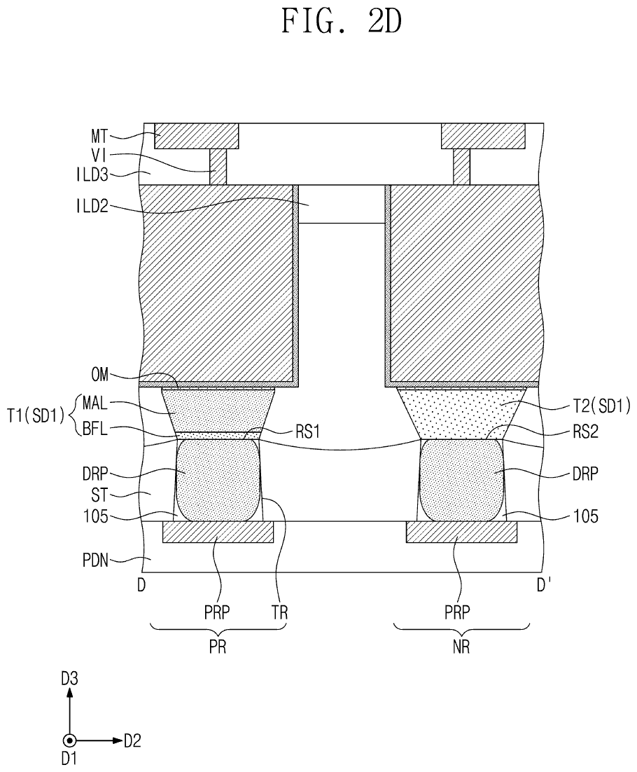

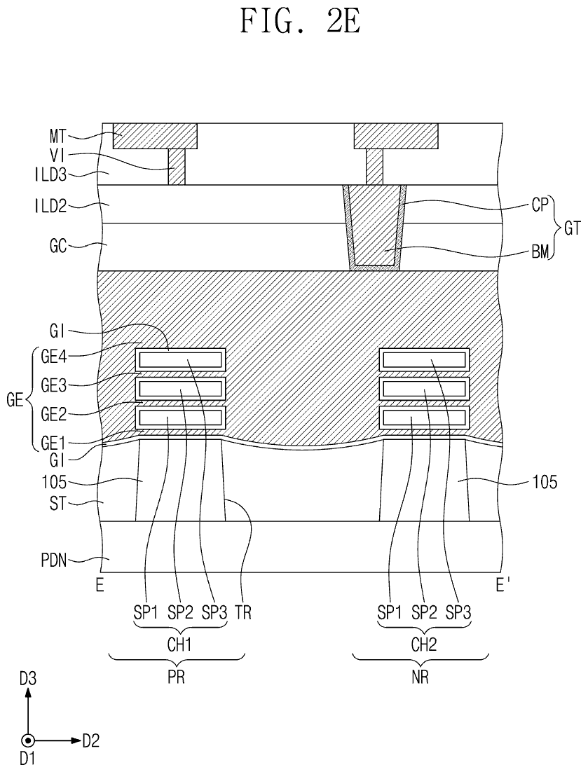

FIG. 1 is a plan view illustrating an integrated circuit device according to an embodiment of the inventive concept; and FIGS. 2A to 2E are sectional views taken along lines A-A′, B-B′, C-C′, D-D′, and E-E′, respectively, of FIG. 1. Referring to FIGS. 1 and 2A to 2E, a substrate 105 including a PMOSFET region PR and an NMOSFET region NR may be provided. In an embodiment, the substrate 105 may include a silicon-based insulating layer. That is, the substrate 105 may be an insulating substrate. For example, the substrate 105 may include at least one of silicon oxide (SiO₂), silicon nitride (SiN), or silicon oxynitride (SiON). In the present specification, each of the expressions of “A or B”, “at least one of A and B”, “at least one of A or B”, “A, B, or C”, “at least one of A, B, and C”, and “at least one of A, B, or C” may be used to represent one of the elements enumerated in the expression or any possible combination of the enumerated elements.

The PMOSFET and NMOSFET regions PR and NR may be extended in a first direction D1 and may be spaced apart from each other in a second direction D2. The first and second directions D1 and D2 may be parallel to a bottom surface of the substrate 105 and may be non-parallel (e.g., orthogonal) to each other. An insulating pattern may be defined by a trench TR of the substrate 105. When viewed in a plan view, the insulating pattern may be a portion of the substrate 105. The portion of the substrate 105 may protrude in a third direction D3. The third direction D3 may be perpendicular to the bottom surface of the substrate 105.

A device isolation pattern ST may be provided between the insulating patterns to fill the trench TR. The device isolation pattern ST may enclose the insulating patterns. The device isolation pattern ST may include an insulating material. The device isolation pattern ST may be formed of or include silicon oxide (SiO₂).

A first channel pattern CH1 may be provided on the PMOSFET region PR of the substrate 105, and a second channel pattern CH2 may be provided on the NMOSFET region NR of the substrate 105. In other words, the first and second channel patterns CH1 and CH2 may be provided on the insulating pattern. In an embodiment, a plurality of first channel patterns CH1 may be provided to be spaced apart from each other in the first direction D1. In an embodiment, a plurality of second channel patterns CH2 may be provided to be spaced apart from each other in the first direction D1. Each of the first and second channel patterns CH1 and CH2 may include a first semiconductor pattern SP1, a second semiconductor pattern SP2, and a third semiconductor pattern SP3, which are adjacent to each other in the third direction D3, but the inventive concept is not limited to this example. In an embodiment, each of the first and second channel patterns CH1 and CH2 may include four or more semiconductor patterns. In an embodiment, each of the first to third semiconductor patterns SP1, SP2, and SP3 may be formed of or include crystalline silicon.

First recesses RS1, which will be described below, may be defined between the first channel patterns CH1, which are adjacent to each other in the first direction D1. Second recesses RS2, which will be described below, may be defined between the second channel patterns CH2, which are adjacent to each other in the first direction D1.

A first source/drain pattern SD1 may be provided on the PMOSFET region PR of the substrate 105, and a second source/drain pattern SD2 may be provided on the NMOSFET region NR of the substrate 105. In an embodiment, the first source/drain pattern SD1 and the second source/drain pattern SD2 may be provided on the insulating pattern. The first source/drain pattern SD1 may be provided to fill the first recess RS1, and the second source/drain pattern SD2 may be provided to fill the second recess RS2. Each of the first and second source/drain patterns SD1 and SD2 may be electrically connected to the first to third semiconductor patterns SP1, SP2, and SP3. The first source/drain patterns SD1 may be impurity regions of a first conductivity type (e.g., p-type), and the second source/drain patterns SD2 may be impurity regions of a second conductivity type (e.g., n-type). A pair of the first source/drain patterns SD1 may be electrically connected to each other through the first channel pattern CH1. A pair of the second source/drain patterns SD2 may be electrically connected to each other through the second channel pattern CH2.

The first source/drain patterns SD1 may be formed of or include a semiconductor material (e.g., SiGe) whose lattice constant is greater than that of the first channel pattern CH1. In this case, the pair of the first source/drain patterns SD1 may exert a compressive stress on the first channel patterns CH1 therebetween. The second source/drain patterns SD2 may be formed of or include the same semiconductor element (e.g., Si) as the second channel pattern CH2.

The first source/drain pattern SD1 may include a buffer layer BFL covering an inner surface of the first recess RS1 and a main layer MAL filling most of a remaining portion of the first recess RS1. In an embodiment, each of the buffer and main layers BFL and MAL may be formed of or include silicon germanium (SiGe). The buffer layer BFL may contain a relatively low concentration of germanium (Ge). The main layer MAL may contain a relatively high concentration of germanium. In an embodiment, the buffer layer BFL may contain only silicon (Si).

The first and second source/drain patterns SD1 and SD2 may include a first pattern T1, which is electrically connected to a power delivery network layer PDN to be described below, and a second pattern T2, which is electrically connected to an active contact AC to be described below.

A gate electrode GE may be provided on the first and second channel patterns CH1 and CH2 to cross the first and second channel patterns CH1 and CH2. In an embodiment, a plurality of gate electrodes GE may be provided. The gate electrodes GE may be extended in the second direction D2 and may be spaced apart from each other in the first direction D1. As shown, the gate electrode GE may include inner electrodes GE1-GE3 and an outer electrode GE4. The inner electrodes GE1-GE3 of the gate electrode GE may be provided between each of the plurality of semiconductor patterns SP1, SP2, SP3, and between the first semiconductor pattern SP1 and the substrate 105. The outer electrode GE4 of the gate electrode GE may be provided on the uppermost semiconductor pattern. In an embodiment, the inner electrodes GE1-GE3 of the gate electrode GE may include a first inner electrode GE1, a second inner electrode GE2, and a third inner electrode GE3, but the inventive concept is not limited to this example. In an embodiment, the inner electrodes of the gate electrode GE may include four or more inner electrodes. In detail, the first inner electrode GE1 may be interposed between the substrate 105 and the first semiconductor pattern SP1. The second inner electrode GE2 may be interposed between the first semiconductor pattern SP1 and the second semiconductor pattern SP2. The third inner electrode GE3 may be interposed between the second semiconductor pattern SP2 and the third semiconductor pattern SP3. The outer electrode GE4 of the gate electrode GE may be provided on the third semiconductor pattern SP3.

The gate electrode GE may include a first metal pattern and a second metal pattern on the first metal pattern. The first metal pattern may include a work-function metal, which can be used to adjust a threshold voltage of the transistor. The first metal pattern may be formed of or include at least one of metallic materials (e.g., Ti, Mo, W, Cu, Al, Ta, Ru, Ir, and Co) or metal nitride materials (e.g., nitride materials of Ti, Mo, W, Cu, Al, Ta, Ru, Ir, and Co). In an embodiment, the first metal pattern may further include carbon (C). The first metal pattern may be formed of or include at least one of metallic materials having different work functions. In an embodiment, the second metal pattern may be formed of or include at least one of metallic materials (e.g., Ti, Mo, W, Cu, Al, Ta, Ru, Ir, and Co) whose electric resistances are lower than that of the first metal pattern. The first to third inner electrodes GE1, GE2, and GE3 of the gate electrode GE may include the first metal pattern. In an embodiment, the outer electrode GE4 of the gate electrode GE may include the first metal pattern and the second metal pattern.

A gate capping pattern GC may be provided on a top surface of the gate electrode GE. In detail, the gate capping pattern GC may be provided on the outer electrode GE4 of the gate electrode GE. In an embodiment, the gate capping pattern GC may be formed of or include at least one of SiON, SiCN, SiOCN, or SiN.

Gate spacers GS may be provided on side surfaces of the outer electrode GE4 of the gate electrode GE and may be extended to side surfaces of the gate capping pattern GC. The gate spacer GS may include a single layer or a composite layer. In an embodiment, the gate spacer GS may be formed of or include at least one of SiON, SiCN, SiOCN, or SiN.

A gate insulating pattern GI may be interposed between the gate electrode GE and the first to third semiconductor patterns SP1, SP2, and SP3. The gate insulating pattern GI may cover a top surface, a bottom surface, and opposite side surfaces of each of the first to third semiconductor patterns SP1, SP2, and SP3. The gate insulating pattern GI may cover a top surface of the device isolation pattern ST below the gate electrode GE. The gate insulating pattern GI may be interposed between the outer electrode GE4 and the gate spacer GS. The gate insulating pattern GI may be formed of or include at least one of silicon oxide (SiO₂), silicon oxynitride (SiON), or high-k dielectric materials. In the present specification, the high-k dielectric material may be defined as a material having a dielectric constant higher than that of silicon oxide.

Although not shown, an inner spacer may be interposed between a side surface of the second source/drain pattern SD2 and a side surface of the gate electrode GE. In an embodiment, the inner spacer may be interposed between the first to third inner electrodes GE1-GE3 and the second source/drain pattern SD2. The inner spacer may include an insulating material.

A first interlayer insulating layer ILD1 may be provided on the substrate 105. The first interlayer insulating layer ILD1 may cover the gate spacers GS and the first and second source/drain patterns SD1 and SD2. A top surface of the first interlayer insulating layer ILD1 may be located at substantially the same level as a top surface of the gate capping pattern GC and a top surface of the gate spacer GS. A second interlayer insulating layer ILD2 may be provided on the first interlayer insulating layer ILD1 to cover the gate capping pattern GC. A third interlayer insulating layer ILD3 may be provided on the second interlayer insulating layer ILD2. In an embodiment, the first to third interlayer insulating layers ILD1, ILD2, and ILD3 may be formed of or include silicon oxide (SiO₂).

The active contact AC may penetrate the first and second interlayer insulating layers ILD1 and ILD2 in the third direction D3. In an embodiment, a plurality of active contacts AC may be provided, and a lower portion of each of the active contacts AC may be buried in an upper portion of the second pattern T2 of the source/drain pattern SD1 or SD2. That is, the active contact AC may be a contact, which is formed through a frontside surface of the substrate 105.

The active contact AC may include a conductive pattern CP penetrating the first and second interlayer insulating layers ILD1 and ILD2 and a barrier pattern BM enclosing the conductive pattern CP. In an embodiment, the conductive pattern CP may be formed of or include at least one of metallic materials (e.g., Ti, Mo, W, Cu, Al, Ta, Ru, Ir, and Co). As an example, the barrier pattern BM may be formed of or include at least one of metal nitride materials (e.g., nitride materials of Ti, Mo, W, Cu, Al, Ta, Ru, Ir, and Co).

An ohmic pattern OM may be interposed between the active contact AC and the second pattern T2 of the source/drain pattern SD1 or SD2. Thus, contact resistance characteristics between the active contact AC and the second pattern T2 of the source/drain pattern SD1 or SD2 may be improved. In an embodiment, the ohmic pattern OM may be formed of or include at least one of metal silicide materials (e.g., silicide materials of Ti, Mo, W, Cu, Al, Ta, Ru, Ir, and Co).

As shown in cross section in FIGS. 2A-2E, metal patterns MT may be provided in the third interlayer insulating layer ILD3; and vias VI may be interposed between the metal patterns MT and the active contacts AC. The metal patterns MT may be electrically connected to the active contacts AC through the vias VI. In an embodiment, gate contacts (not shown) may be connected to the gate electrodes GE, and the metal patterns MT may be electrically connected to the gate contacts through the vias VI. In an embodiment, although not illustrated in the drawings, the metal patterns MT and the vias VI may be alternately stacked to form a multi-layered structure. The metal patterns MT and the vias VI may be formed of or include at least one of metallic materials (e.g., Ti, Mo, W, Cu, Al, Ta, Ru, Ir, and Co).

The power delivery network layer PDN may be provided on the bottom surface of the substrate 105. The power delivery network layer PDN may include a plurality of lower interconnection lines PRP, which are electrically connected to the source/drain patterns SD1 and SD2 through a backside conductive structure BCS to be described below. In an embodiment, the power delivery network layer PDN may include an interconnection network, which is used to apply a source voltage. In an embodiment, the power delivery network layer PDN may include an interconnection network, which is used to apply a drain voltage.

The backside conductive structure BCS may be provided in the substrate 105. The backside conductive structure BCS may penetrate the substrate 105 and may be interposed between the first pattern T1 of the source/drain pattern SD1 or SD2 and the power delivery network layer PDN. The backside conductive structure BCS may be provided to electrically connect the first pattern T1 of the source/drain pattern SD1 or SD2 to the power delivery network layer PDN. The backside conductive structure BCS may be a backside active contact, which is formed through a backside surface of the substrate 105, unlike the active contact AC described above.

A bottom surface of the backside conductive structure BCS may be in direct contact with the lower interconnection line PRP of the power delivery network layer PDN. A top surface of the backside conductive structure BCS may be in direct contact with the first pattern T1 of the source/drain pattern SD1 or SD2. The top surface of the backside conductive structure BCS may be a curved surface that is convex toward the first pattern T1. A width of the backside conductive structure BCS in the first direction D1 may decrease as a distance to the first pattern T1 decreases.

The backside conductive structure BCS may include a backside conductive pattern BT and a backside barrier pattern BBM enclosing the same. In an embodiment, the backside conductive pattern BT may be formed of or include at least one of metallic materials (e.g., Ti, Mo, W, Cu, Al, Ta, Ru, Ir, and Co). The backside barrier pattern BBM may be formed of or include at least one of metal nitride materials (e.g., nitrides of Ti, Mo, W, Cu, Al, Ta, Ru, Ir, and Co).

A lower insulating pattern DRP may be provided in the substrate 105. In other words, the lower insulating pattern DRP may be buried in the substrate 105. The lower insulating pattern DRP may be provided below the second pattern T2 of the source/drain pattern SD1 or SD2. The second pattern T2 of the source/drain pattern SD1 or SD2 may be vertically overlapped with the lower insulating pattern DRP and may be in contact with the lower insulating pattern DRP.

The lower insulating pattern DRP may be in direct contact with the lower interconnection line PRP of the power delivery network layer PDN. In detail, the lower insulating pattern DRP may be in direct contact with a portion of a lower interconnection line RPR. A bottom surface of the lower insulating pattern DRP may be in direct contact with the lower interconnection line PRP of the power delivery network layer PDN. For example, a level of the bottom surface of the lower insulating pattern DRP may be substantially equal to a level of the bottom surface of the backside conductive structure BCS. The bottom surface of the lower insulating pattern DRP and the bottom surface of the backside conductive structure BCS may be substantially coplanar with each other. Opposite side surfaces of the lower insulating pattern DRP may have a curved shape. The opposite side surfaces may be convex toward the substrate 105.

The lower insulating pattern DRP may have a first height DRP_H in the third direction D3. The backside conductive structure BCS may have a second height BCS_H in the third direction D3. The first height DRP_H may be defined as a vertical distance from the bottom surface of the lower insulating pattern DRP to the uppermost surface of the lower insulating pattern DRP. The second height BCS_H may be defined as a vertical distance from the bottom surface of the backside conductive structure BCS to the uppermost surface of the backside conductive structure BCS. The second height BCS_H may be larger than the first height DRP_H. In an embodiment, the second height BCS_H may be substantially equal to the first height DRP_H.

The uppermost surface of the lower insulating pattern DRP may be located at a level lower than the uppermost surface of the backside conductive structure BCS. In an embodiment, the uppermost surface of the lower insulating pattern DRP and the uppermost surface of the backside conductive structure BCS may be located at the same level. The uppermost surface of the lower insulating pattern DRP may be located at substantially the same level as a bottom surface of the gate insulating pattern GI enclosing the first inner electrode GE1. The uppermost surface of the backside conductive structure BCS may be located at a level that is higher than the bottom surface of the gate insulating pattern GI and is lower than the top surface of the gate insulating pattern GI.

The uppermost surface of the lower insulating pattern DRP may be located at a first level LV1 in the third direction D3, and the uppermost surface of the backside conductive structure BCS may be located at a second level LV2 in the third direction D3. The first level LV1 may be defined as a vertical position of the uppermost surface of the lower insulating pattern DRP in the third direction D3. The second level LV2 may be defined as a vertical position of the uppermost surface of the backside conductive structure BCS in the third direction D3. The second level LV2 may be higher than the first level LV1. In an embodiment, the second level LV2 and the first level LV1 may be substantially equal to each other. The second level LV2 may be higher than a bottom surface of the first inner electrode GE1 and may be lower than a top surface of the first inner electrode GE1.

The lower insulating pattern DRP may be formed of or include an insulating material different from the substrate 105. In an embodiment, the lower insulating pattern DRP and the substrate 105 may be formed of or include the same insulating material. The lower insulating pattern DRP may be formed of or include at least one of silicon oxide (SiO₂), silicon nitride (SiN), aluminum oxide (Al₂O₃), or aluminum nitride (AlN). The substrate 105 may include at least one of silicon oxide (SiO₂), silicon nitride (SiN), or silicon oxynitride (SiON), as described above.

Since the lower insulating pattern DRP includes the insulating material, a short phenomenon may not occur, even when the lower insulating pattern DRP is in direct contact with the lower interconnection line PRP of the power delivery network layer PDN. In other words, it may be possible to prevent a short phenomenon between a power delivery network layer DPN and the source/drain patterns SD1 and SD2. Thus, the reliability characteristics of the integrated circuit device may be improved.

Although not shown, a width of the lower insulating pattern DRP in the first direction D1 may increase as a distance to the power delivery network layer PDN decreases. This may be because a chamfering process is performed to remove a portion of the lower insulating pattern DRP that is vulnerable to an overhang issue. After the chamfering process, opposite side surfaces of the lower insulating pattern DRP may be formed to include at least one curved portion and a flat portion with a specific slope. In this case, the largest width of the lower insulating pattern DRP in the first direction D1 may be larger than the largest width of the backside conductive structure BCS in the first direction D1.

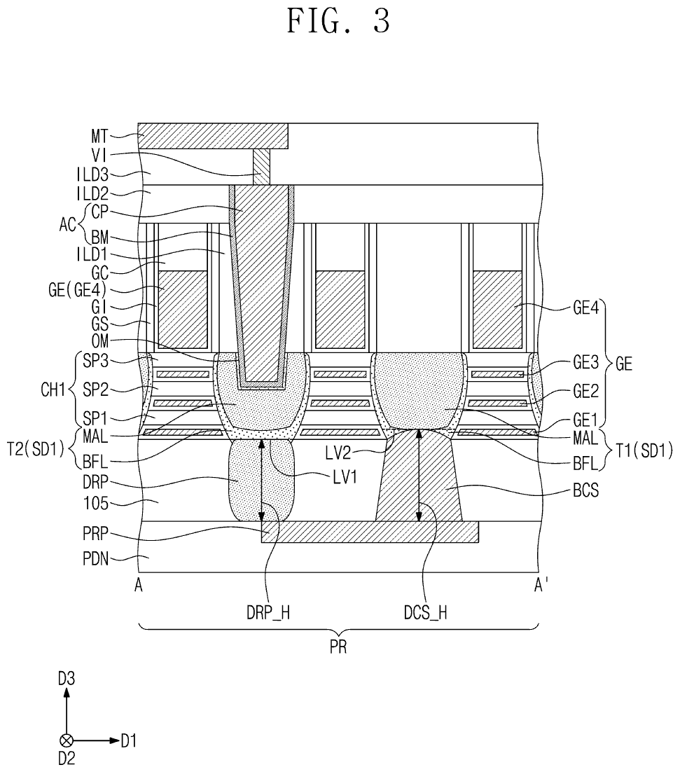

Hereinafter, an integrated circuit device according to an embodiment of the inventive concept will be described with reference to FIG. 3, which is a sectional view illustrating an integrated circuit device according to an embodiment of the inventive concept. In the following description, a previously-described element may be identified by the same reference number without repeating an overlapping description thereof, for concise description. Referring to FIG. 3, the backside conductive structure BCS may include a backside conductive pattern. The backside conductive pattern may be formed of or include at least one of metallic materials (e.g., Ti, Mo, W, Cu, Al, Ta, Ru, Ir, and Co). The backside conductive structure BCS may not include the backside barrier pattern. That is, side surfaces of the backside conductive pattern of the backside conductive structure BCS may be in direct contact with the substrate 105.

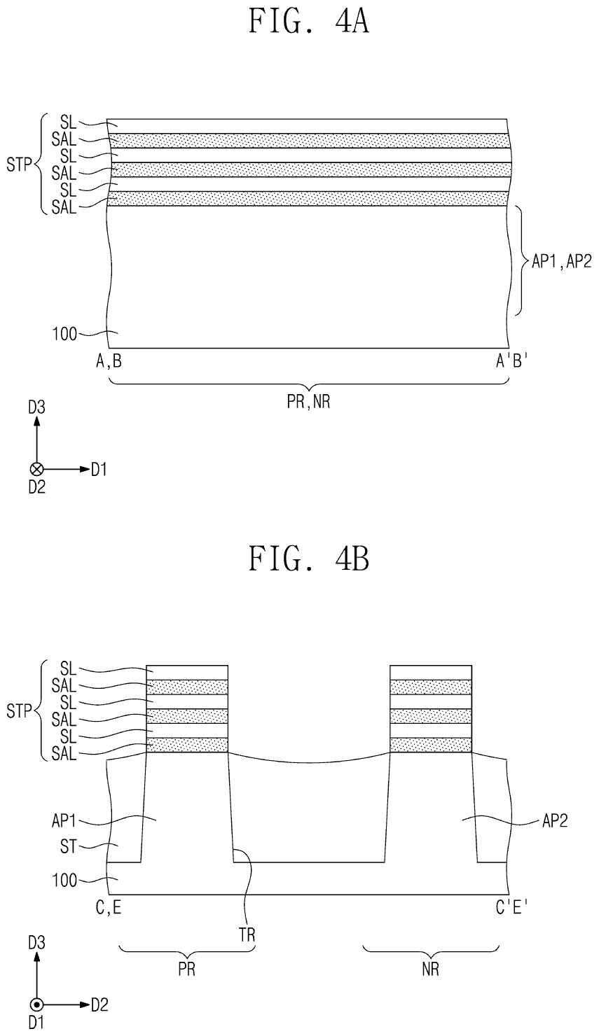

FIGS. 4A to 11B are diagrams illustrating a method of fabricating an integrated circuit device, according to an embodiment of the inventive concept. Referring to FIGS. 1, 4A, and 4B, a semiconductor substrate 100 including the PMOSFET and NMOSFET regions PR and NR may be provided. In an embodiment, the semiconductor substrate 100 may be a single-crystalline silicon substrate, a silicon-germanium substrate, or a semiconductor substrate (e.g., a silicon-on-insulator (SOI) substrate) including a semiconductor material. Stacking patterns STP may be formed on the PMOSFET and NMOSFET regions PR and NR. In an embodiment, the formation of the stacking patterns STP may include alternately stacking semiconductor layers SL and sacrificial layers SAL on the semiconductor substrate 100, forming mask patterns (not shown) to extend in the first direction D1, and performing a patterning process using the mask patterns as an etch mask. During the patterning process, portions of the semiconductor substrate 100 may be removed to form the trenches TR defining a first active pattern AP1 and a second active pattern AP2.

The first active pattern AP1 may be formed on the PMOSFET region PR, and the second active pattern AP2 may be formed on the NMOSFET region NR. The first and second active patterns AP1 and AP2 may be extended in the first direction D1. The device isolation patterns ST may be formed to fill the trenches TR.

The sacrificial layers SAL may include a material having an etch selectivity with respect to the semiconductor layers SL. Thus, the semiconductor layers SL may not be substantially removed in a subsequent process of removing the sacrificial layers SAL. The semiconductor and sacrificial layers SL and SAL may be formed of or include at least one of silicon (Si), germanium (Ge), or silicon germanium (SiGe), but the material of the sacrificial layers SAL may be different from that of the semiconductor layers SL.

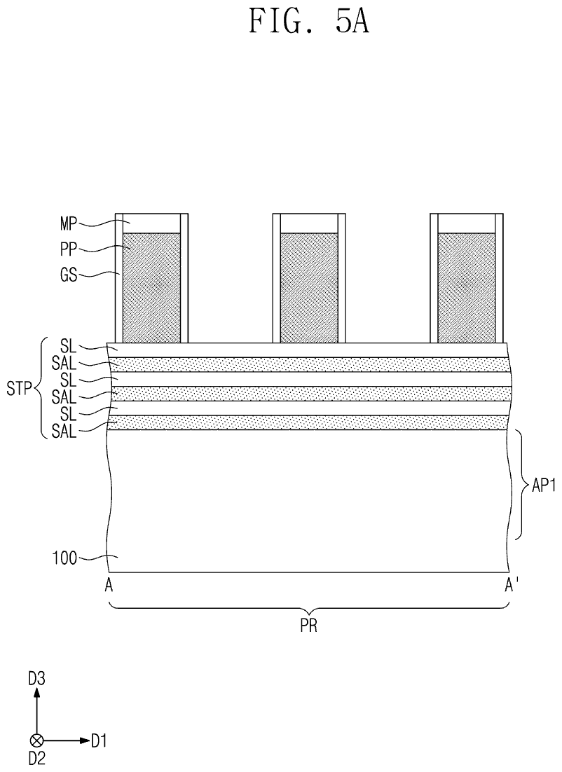

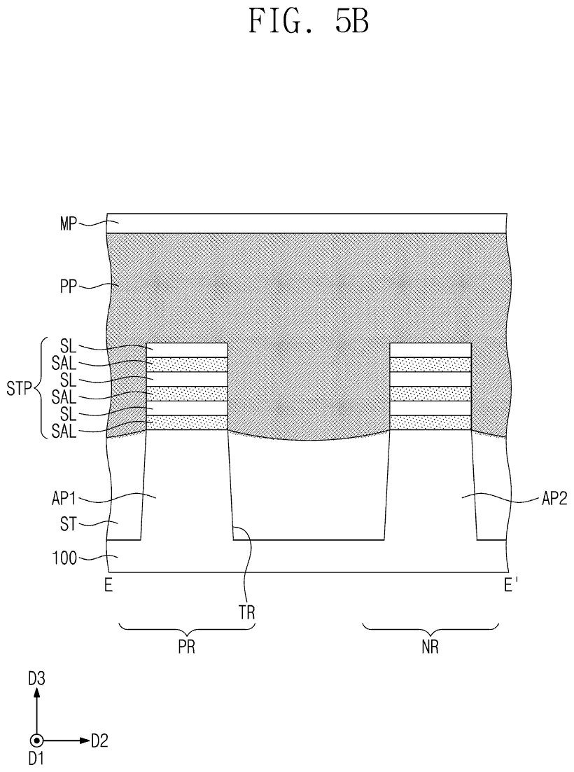

Referring to FIGS. 1, 5A, and 5B, sacrificial patterns PP may be formed on the semiconductor substrate 100 to extend in the second direction D2. The sacrificial patterns PP may be formed to cover the top surfaces of the device isolation patterns ST and the side and top surfaces of the stacking patterns STP. In an embodiment, the formation of the sacrificial patterns PP may include forming a sacrificial layer (not shown) on the semiconductor substrate 100, forming hard mask patterns MP on the sacrificial layer, and removing a portion of the sacrificial layer using the hard mask patterns MP as an etch mask to form the sacrificial patterns PP. In an embodiment, the sacrificial pattern PP may be formed of or include polysilicon. Next, the gate spacers GS may be formed on side surfaces of the sacrificial patterns PP.

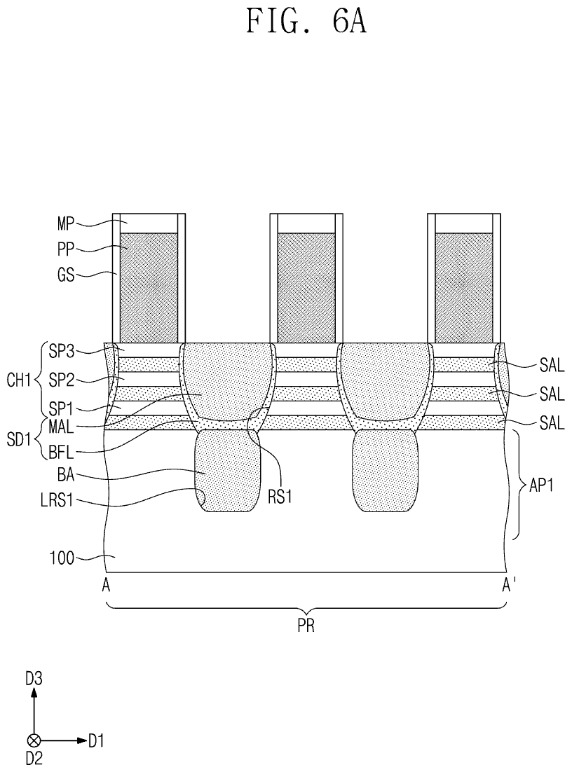

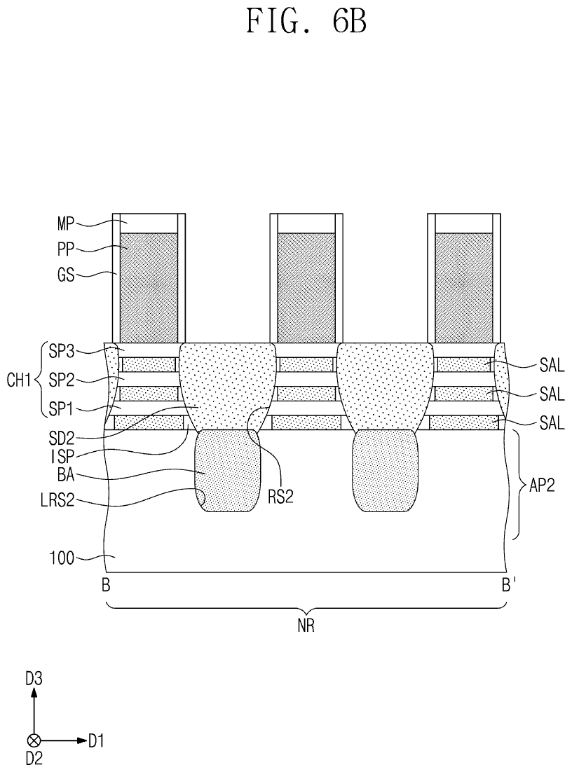

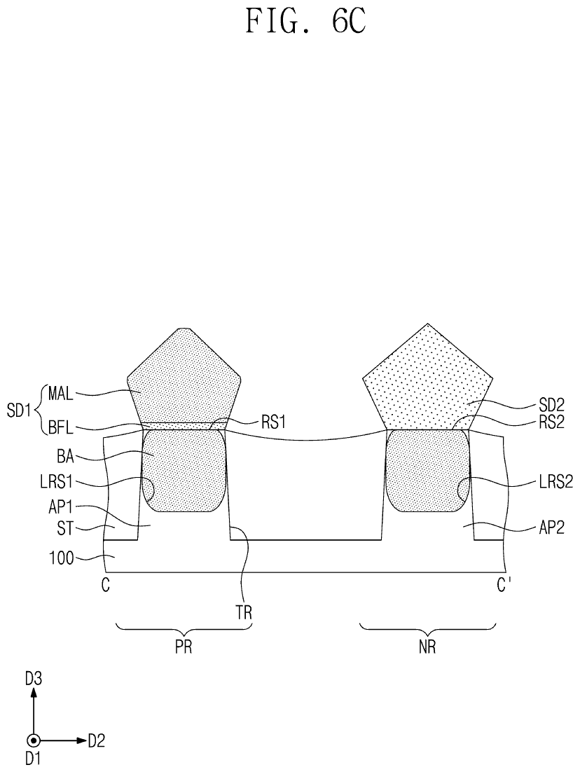

Referring to FIGS. 1 and 6A to 6C, the first recesses RS1 may be formed in the stacking pattern STP on the first active pattern AP1. The second recesses RS2 may be formed in the stacking pattern STP on the second active pattern AP2. In an embodiment, the first and second recesses RS1 and RS2 may be formed by removing portions of the stacking pattern STP using the hard mask patterns MP as an etch mask.

The semiconductor layers SL on the first active pattern AP1 may be divided into the first channel patterns CH1, which are separated from each other in the first direction D1, by the first recesses RS1. The semiconductor layers SL on the second active pattern AP2 may be divided into the second channel patterns CH2, which are spaced apart from each other in the first direction D1, by the second recesses RS2. Each of the first and second channel patterns CH1 and CH2 may include the first to third semiconductor patterns SP1, SP2, and SP3.

A portion of the sacrificial layer SAL exposed through the second recess RS2 may be replaced with an insulating material, and as a result, inner spacers ISP may be formed on opposite side surfaces of the sacrificial layer SAL. A first lower recess LRS1 may be disposed below the first recess RS1. A second lower recess LRS2 may be disposed below the second recess RS2. A backside alignment pattern BA may be formed by a SEG process, in which the semiconductor substrate 100 is used as a seed layer, to fill the first and second lower recesses LRS1 and LRS2. In an embodiment, the backside alignment pattern BA may be formed of or include silicon-germanium (SiGe).

The first source/drain patterns SD1 may be formed in the first recesses RS1. The first source/drain patterns SD1 may be formed by a SEG process, in which the first to third semiconductor patterns SP1, SP2, and SP3 and the backside alignment patterns BA on the PMOSFET region PR are used as a seed layer. In an embodiment, during the formation of the first source/drain pattern SD1, p-type impurities (e.g., boron, gallium, or indium) may be injected into the first source/drain pattern SD1 in an in-situ doping manner. As another example, the impurities may be injected into the first source/drain pattern SD1, after the formation of the first source/drain pattern SD1.

The second source/drain patterns SD2 may be formed in the second recesses RS2. The second source/drain patterns SD2 may be formed by a SEG process, in which the first to third semiconductor patterns SP1, SP2, and SP3 and the backside alignment patterns BA on the NMOSFET region NR are used as a seed layer. In an embodiment, during the formation of the second source/drain pattern SD2, n-type impurities (e.g., phosphorus, arsenic, or antimony) may be injected into the second source/drain pattern SD2 in an in-situ doping manner. In another embodiment, the impurities may be injected into the second source/drain pattern SD2, after the formation of the second source/drain pattern SD2.

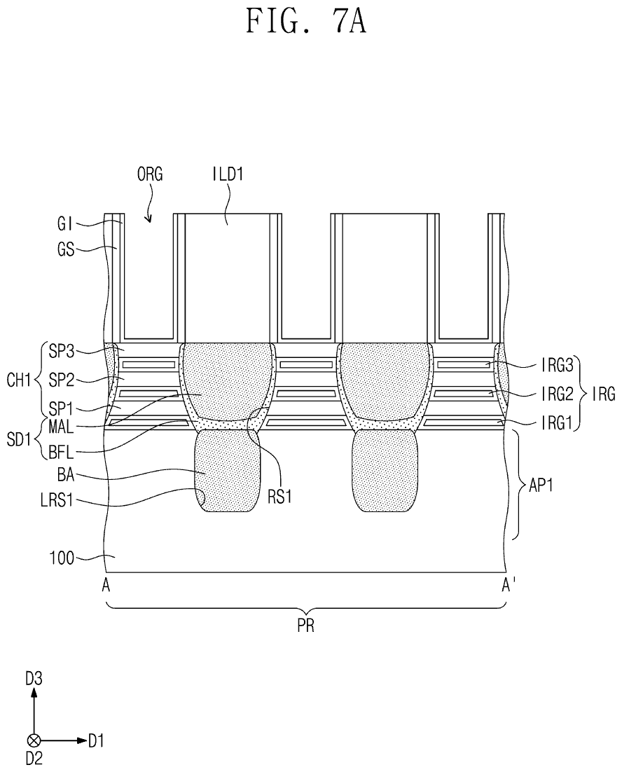

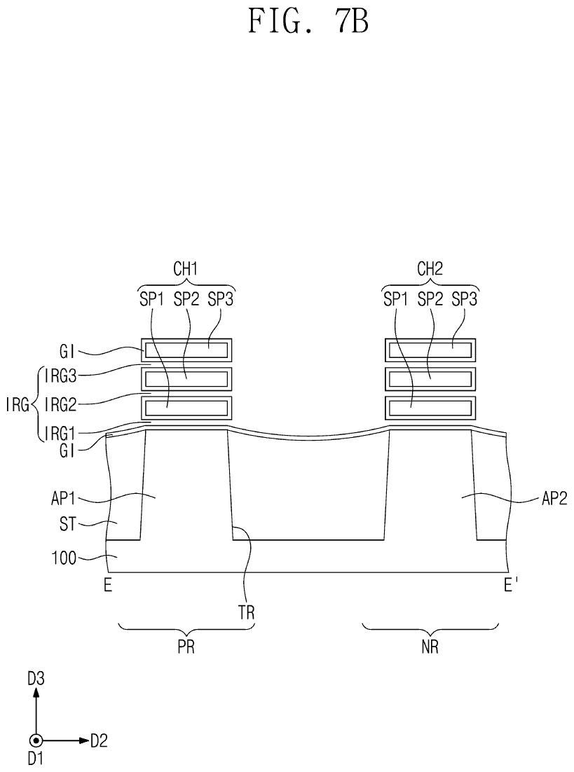

Referring to FIGS. 1, 7A, and 7B, the first interlayer insulating layer ILD1 may be formed to cover the first and second source/drain patterns SD1 and SD2, the hard mask patterns MP, and the gate spacers GS. Thereafter, the first interlayer insulating layer ILD1 on top surfaces of the sacrificial patterns PP may be removed. In an embodiment, the removal process may be performed to remove the hard mask patterns MP and consequently to expose the sacrificial patterns PP.

Thereafter, the exposed sacrificial patterns PP may be removed to form outer regions ORG. The first and second channel patterns CH1 and CH2 and the sacrificial layers SAL may be exposed to the outside through the outer region ORG.

Next, the exposed sacrificial layers SAL may be selectively removed. Here, due to the high etch selectivity between the sacrificial layers SAL and the first to third semiconductor patterns SP1, SP2, and SP3, it may be possible to prevent or suppress the first to third semiconductor patterns SP1, SP2, and SP3 from being removed during the process of removing the sacrificial layers SAL.

Inner regions IRG may be empty regions which are formed by removing the sacrificial layers SAL. In detail, the inner regions IRG may be formed between the first to third semiconductor patterns SP1, SP2, and SP3. The inner regions IRG may include first to third inner regions IRG1, IRG2, and IRG3, which are spaced apart from each other in the third direction D3.

The gate insulating pattern GI may be formed in each of the inner regions IRG and the outer region ORG. The gate insulating pattern GI may be formed to enclose each of the first to third semiconductor patterns SP1, SP2, and SP3. The gate insulating pattern GI may be formed to have a constant thickness.

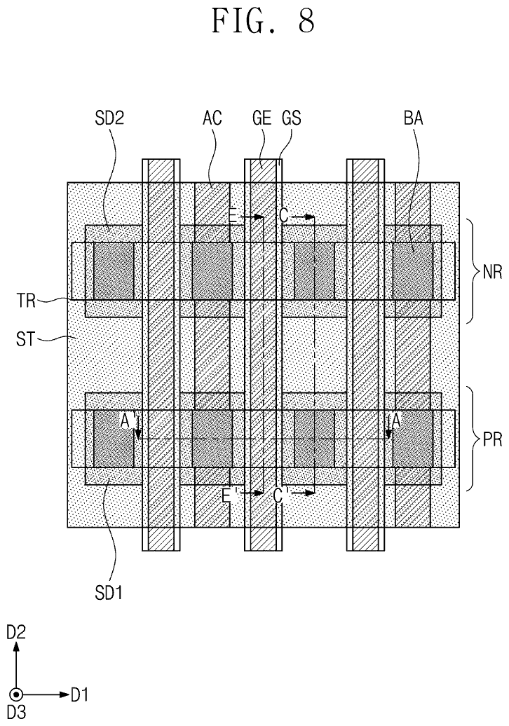

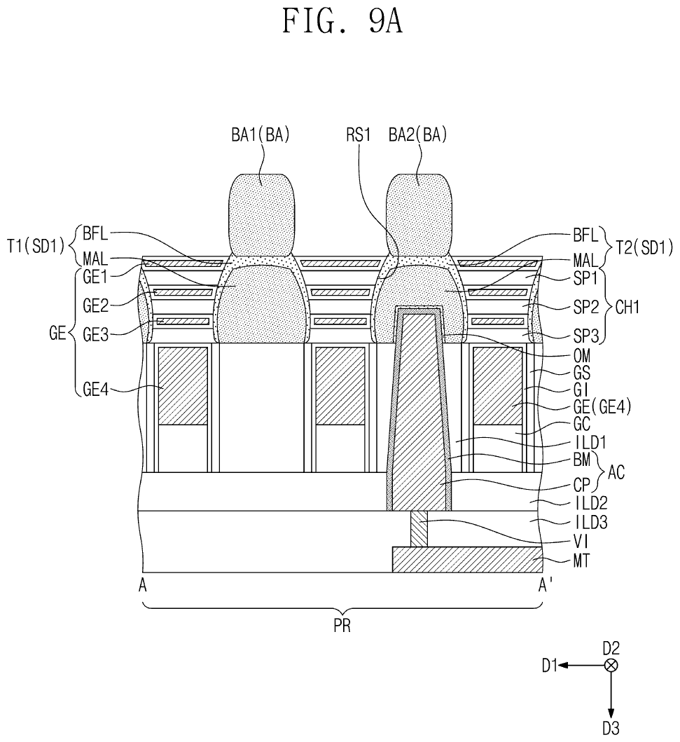

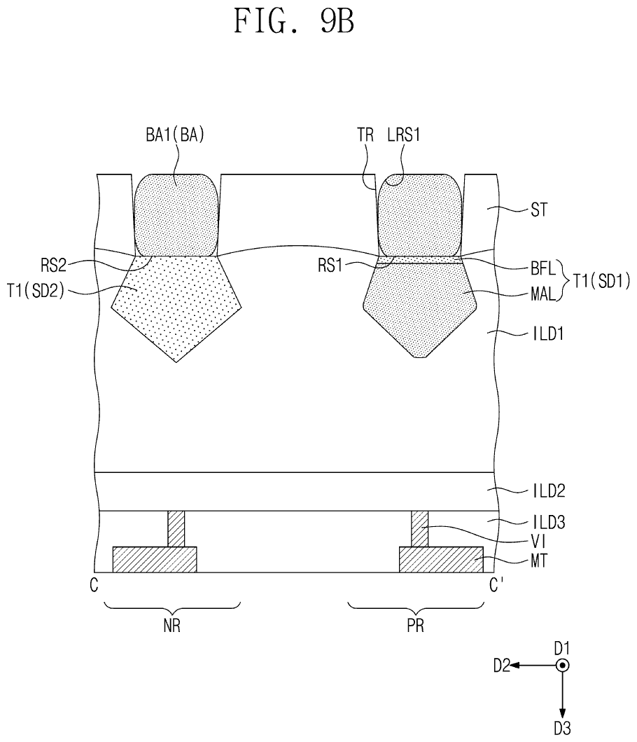

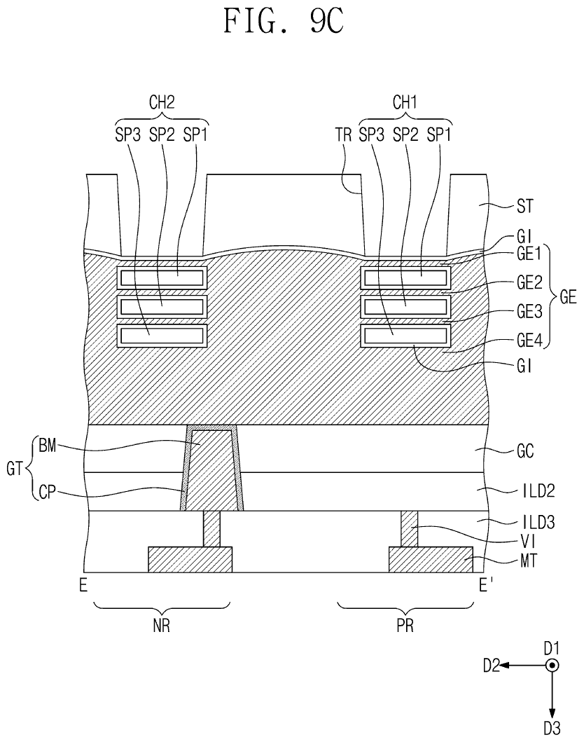

Referring to FIGS. 8 and 9A to 9C, the gate electrode GE may be formed on the gate insulating pattern GI. The gate electrode GE may include the inner electrodes (e.g., the first to third inner electrodes GE1, GE2, and GE3), which are formed in the first to third inner regions IRG1, IRG2, and IRG3, respectively, and the outer electrode GE4, which is formed in the outer region ORG. Next, the gate capping pattern GC may be formed on the outer electrode GE4.

The second interlayer insulating layer ILD2 may be formed on the first interlayer insulating layer ILD1 and the gate capping pattern GC. The active contacts AC may be formed to penetrate the first and second interlayer insulating layers ILD1 and ILD2 and may be connected to the first and second source/drain patterns SD1 and SD2, respectively. Each of the first and second source/drain patterns SD1 and SD2 may include the first pattern T1, which is not connected to the active contact AC, and the second pattern T2, which is electrically connected to the active contact AC. The backside alignment pattern BA may include a first backside alignment pattern BA1 below the first pattern T1 and a second backside alignment pattern BA2 below the second pattern T2.

Gate contacts GT may be formed to penetrate the second interlayer insulating layer ILD2 and the gate capping pattern GC and may be connected to the gate electrodes GE. The formation of the active and gate contacts AC and GT may include forming the barrier pattern BM and forming the conductive pattern CP on the barrier pattern BM. The ohmic pattern OM may be further formed between the active contact AC and the second pattern T2 of each of the first and second source/drain patterns SD1 and SD2. The third interlayer insulating layer ILD3 may be formed on the second interlayer insulating layer ILD2 and the active contacts AC. The metal patterns MT and the vias VI may be formed in the third interlayer insulating layer ILD3.

The semiconductor substrate 100 of FIGS. 4A and 4B may be inverted, after a back-end-of-line (BEOL) process. Since the semiconductor substrate 100 of FIG. 4A is inverted, the terms ‘top surface’ and ‘upper portion’ in the following description of FIGS. 8 to 11B may mean the ‘bottom surface’ and ‘lower portion’, respectively, in the final structure of the integrated circuit device described with reference to FIGS. 2A to 2E, and the terms ‘bottom surface’ and ‘lower portion’ may mean the ‘top surface’ and ‘upper portion’, respectively, in the final structure of the integrated circuit device described with reference to FIGS. 2A to 2E.

Referring back to FIGS. 9A to 9C, the semiconductor substrate 100 may be inverted such that a bottom surface of the semiconductor substrate 100 is exposed to the outside, after the BEOL process. The exposed semiconductor substrate 100 may be fully removed. In an embodiment, the removal of the semiconductor substrate 100 may include performing a planarization process on the bottom surface of the semiconductor substrate 100 to reduce a thickness of the semiconductor substrate 100, performing a cleaning process to selectively remove silicon (Si) on the semiconductor substrate 100, and performing an etching process to selectively remove silicon (Si) in the first and second active patterns AP1 and AP2. The cleaning process may be performed until the device isolation patterns ST are exposed to the outside. The etching process may be a dry etching process or a wet etching process. The backside alignment pattern BA may be left, when the etching process is finished. Since the semiconductor substrate 100 is removed, a first backside trench may be formed in a region where the first active pattern AP1 is located. Since the semiconductor substrate 100 is removed, a second backside trench may be formed in a region where the second active pattern AP2 is located (e.g., see FIGS. 9B and 9C).

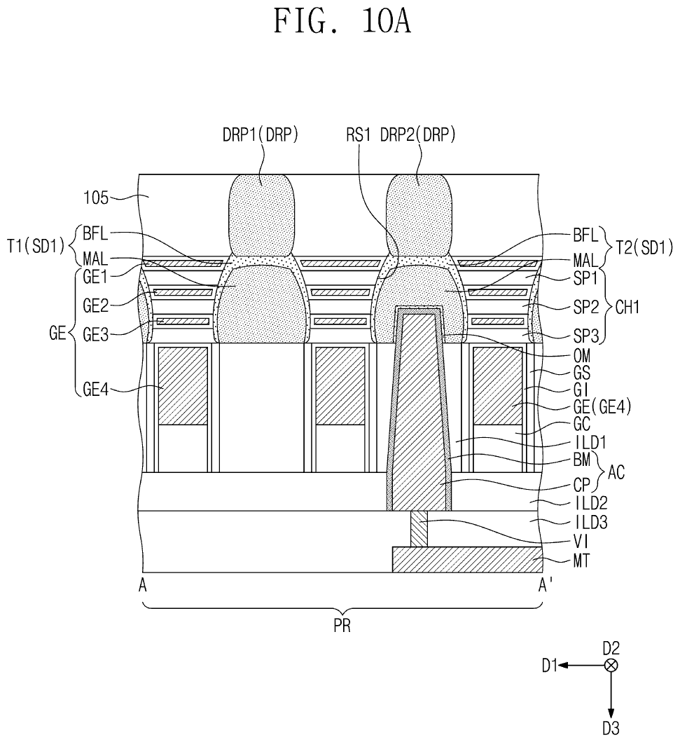

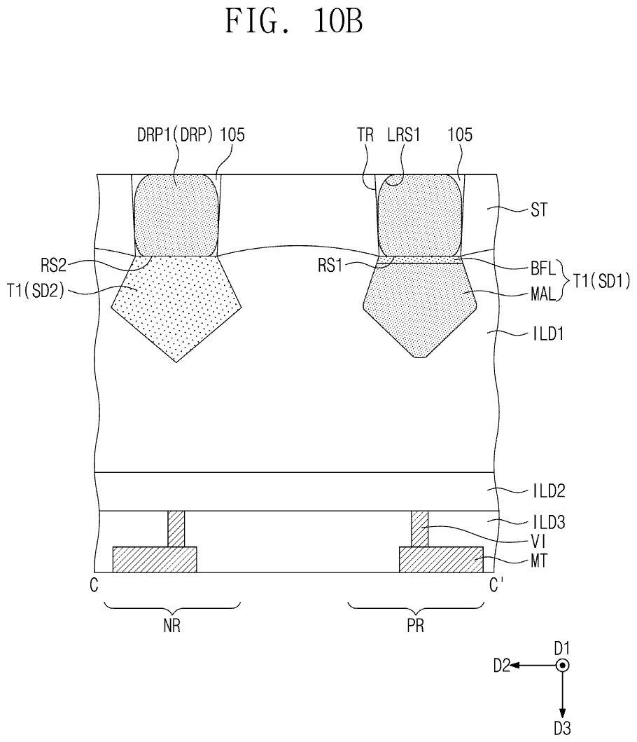

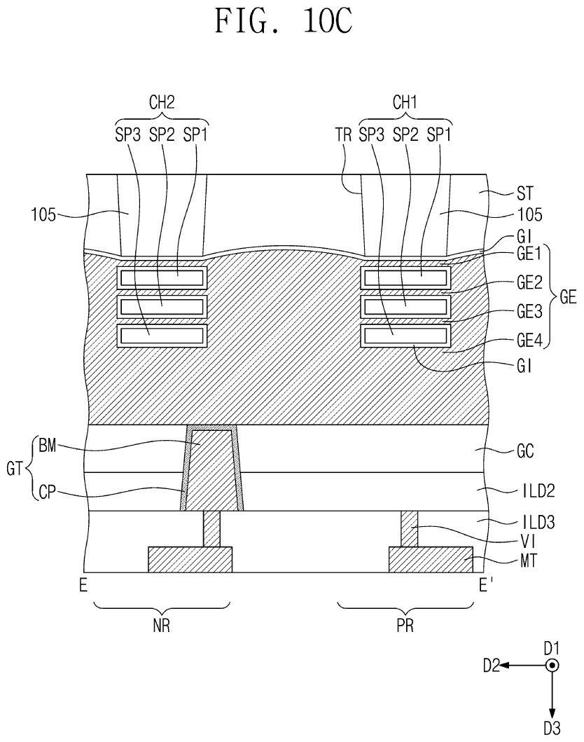

Referring to FIGS. 1 and 10A to 10C, the substrate 105 may be formed to fill empty regions, which are formed by removing the semiconductor substrate 100 of FIG. 4A and the first and second active patterns AP1 and AP2 of FIG. 4A. In detail, the substrate 105 may be formed to fill the first and second backside trenches. In an embodiment, the substrate 105 may be formed by filling an insulating material to a level that is higher than the empty region formed by removing the semiconductor substrate 100 of FIG. 4A. That is, the substrate 105 may be formed to cover the backside alignment pattern BA. Next, a chemical mechanical polishing (CMP) process, in which the backside alignment pattern BA is used as a stopping layer, may be performed on the substrate 105. The substrate 105 and the backside alignment pattern BA may have top surfaces that are substantially coplanar with each other.

The backside alignment pattern BA may be removed, and then, the lower insulating pattern DRP may be formed. The formation of the lower insulating pattern DRP may include performing a cleaning process to selectively remove the backside alignment pattern BA enclosed by the substrate 105 and performing a deposition process to fill a recessed region, which is formed by the cleaning process. The cleaning process may be a wet etching process, which is chosen to selectively remove silicon-germanium. The deposition process may be a chemical vapor deposition (CVD) process, a low pressure CVD (LPCVD) process, a physical vapor deposition (PVD) process, or an atomic layer deposition (ALD) process.

The lower insulating pattern DRP may include a first lower insulating pattern DRP1 on the first pattern T1 of each of the source/drain patterns SD1 and SD2 and a second lower insulating pattern DRP2 on the second pattern T2 of each of the source/drain patterns SD1 and SD2. The lower insulating pattern DRP may include an insulating material. For example, the insulating material may be formed of or include at least one of silicon oxide (SiO₂), silicon nitride (SiN), aluminum oxide (Al₂O₃), or aluminum nitride (AlN).

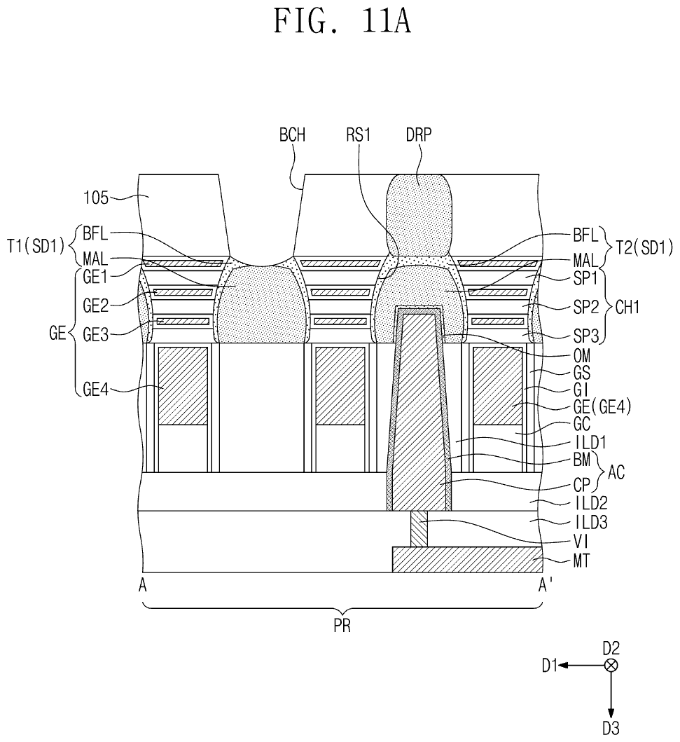

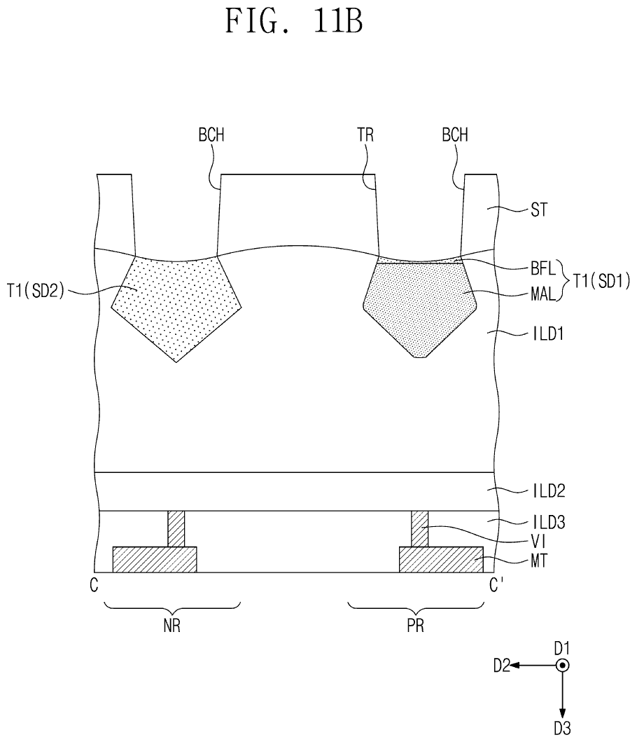

Referring to FIGS. 1 and 11A to 11B, a backside contact hole BCH may be formed on the first pattern T1 to penetrate the substrate 105. Here, the backside contact hole BCH may be formed to further recess an upper portion of the first pattern T1 of each of the first and second source/drain patterns SD1 and SD2. In detail, the formation of the backside contact hole BCH may include forming a hard mask pattern on the substrate 105, performing a dry etching process on the first lower insulating pattern DRP1 using the hard mask pattern, and removing the hard mask pattern. In this case, the lower insulating pattern DRP on the second pattern T2 may not be removed and may be left.

Referring back to FIGS. 1 and 2A to 2D, the backside conductive structure BCS may be formed to fill the backside contact hole BCH. The formation of the backside conductive structure BCS may include forming the backside barrier pattern BBM to conformally cover an inner side surface and an inner bottom surface of the backside contact hole BCH and forming the backside conductive pattern BT on the backside barrier pattern BBM to fill a remaining region of the backside contact hole BCH. In an embodiment, the backside conductive pattern BT may be formed through a single process, and in this case, an interface may not be formed in the backside conductive pattern BT. As a result, the backside conductive pattern BT may have a relatively small electric resistance, and this may make it possible to improve the electrical characteristics of the integrated circuit device. Next, the power delivery network layer PDN may be formed on the bottom surface of the substrate 105.

In a three-dimensional field effect transistor according to an embodiment of the inventive concept, a lower insulating pattern may be formed below a source/drain pattern, and thus, a via pattern, which is used to connect an interconnection line to a contact pattern, may be omitted. In this case, it may be possible to reduce the time it takes to send a signal from a power delivery network layer to the contact pattern, and thus, an operation speed of the integrated circuit device may be increased. In addition, the contact pattern may be formed to have a reduced thickness, and this may make it possible to reduce a contact resistance. Thus, the electrical characteristics of the integrated circuit device may be improved.

In a three-dimensional field effect transistor according to an embodiment of the inventive concept, the lower insulating pattern may include an insulating material (e.g., SiOₓ, SiN, AlOₓ, or AlN), and in this case, it may be possible to prevent a short circuit issue between the power delivery network layer and source/drain pattern. That is, even when an interconnection line of the power delivery network layer is in contact with the lower insulating pattern, there may be no leakage current. Thus, the reliability characteristics of the integrated circuit device may be improved.

While example embodiments of the inventive concept have been particularly shown and described, it will be understood by one of ordinary skill in the art that variations in form and detail may be made therein without departing from the spirit and scope of the attached claims.

What is claimed is:

1. An integrated circuit device, comprising:
a substrate;
a power delivery network layer including a lower interconnection line, on a bottom surface of the substrate;
source/drain patterns including horizontally spaced-apart first and second patterns, on the substrate;
a backside conductive structure that penetrates the substrate and electrically connects the first pattern to the power delivery network layer; and
a lower insulating pattern extending below the second pattern, and in contact with a portion of the lower interconnection line.

2. The device of claim 1, wherein the backside conductive structure comprises a backside conductive pattern and a backside barrier pattern enclosing the backside conductive pattern.

3. The device of claim 1, further comprising an active contact, which is electrically connected to the second pattern.

4. The device of claim 1, wherein the lower insulating pattern has a first height in a direction perpendicular to the substrate; and wherein the backside conductive structure has a second height in the direction perpendicular to the substrate, which is larger than or equal to the first height.

5. The device of claim 4, wherein the first and second heights are equivalent.

6. The device of claim 1, wherein a level of a bottom surface of the lower insulating pattern is equal to a level of a bottom surface of the backside conductive structure.

7. The device of claim 1, wherein opposite side surfaces of the lower insulating pattern have a curved shape.

8. The device of claim 7, wherein the opposite side surfaces has a shape that is convex toward the substrate.

9. The device of claim 1, wherein the substrate and the lower insulating pattern comprise different insulating materials relative to each other.

10. The device of claim 1, wherein the substrate and the lower insulating pattern comprise the same material.

11. The device of claim 1, wherein the substrate comprises at least one of silicon oxide (SiO₂), silicon nitride (SiN), or silicon oxynitride (SiON), and
the lower insulating pattern comprises at least one of silicon oxide (SiO₂), silicon nitride (SiN), aluminum oxide (Al₂O₃), or aluminum nitride (AlN).

12. An integrated circuit device, comprising:
a substrate;
a power delivery network layer on a bottom surface of the substrate;
source/drain patterns including horizontally spaced-apart first and second patterns, on the substrate;
a channel pattern, which extends on a side surface of at least one of the first pattern and the second patterns and includes a stack of a plurality of spaced-apart semiconductor patterns;
a gate electrode extending between the spaced-apart semiconductor patterns;
a backside active contact that penetrates the substrate and electrically connects the first pattern to the power delivery network layer; and
a lower insulating pattern extending below the second pattern, said lower insulating pattern having an uppermost surface that is located at a level lower than or equal to an uppermost surface of the backside active contact.

13. The device of claim 12, wherein the uppermost surface of the lower insulating pattern is located at a first level in a direction perpendicular to the substrate; wherein the uppermost surface of the backside active contact is located at a second level in the direction perpendicular to the substrate; and wherein the second level is higher than or equal to the first level.

14. The device of claim 13, wherein the gate electrode comprises a first inner electrode, a second inner electrode, and a third inner electrode, which extend between adjacent ones of the spaced-apart semiconductor patterns, and an outer electrode, which is provided on the uppermost one of the spaced-apart semiconductor patterns; and wherein the second level is higher than a bottom surface of the first inner electrode and is lower than a top surface of the first inner electrode.

15. The device of claim 12, wherein the gate electrode includes a first inner electrode, a second inner electrode, and a third inner electrode, which extend between adjacent ones of the spaced-apart semiconductor patterns, an outer electrode, which is provided on the uppermost one of the semiconductor patterns, and a gate insulating pattern enclosing the first inner electrode; and wherein the uppermost surface of the lower insulating pattern is located at the same level as a bottom surface of the gate insulating pattern.

16. The device of claim 15, wherein the uppermost surface of the backside active contact is located at a level that is higher than a bottom surface of the gate insulating pattern and is lower than a top surface of the gate insulating pattern.

17. The device of claim 12, wherein the backside active contact comprises at least one of Ti, Mo, W, Cu, Al, Ta, Ru, Ir, or Co.

18. An integrated circuit device, comprising:
a substrate;
a power delivery network layer including a lower interconnection line, on a bottom surface of the substrate;
source/drain patterns including horizontally spaced-apart first and second patterns, on the substrate;
a channel pattern, which extends on a side surface of at least one of the first pattern and the second patterns and includes a stack of a plurality of spaced-apart semiconductor patterns;
a gate electrode extending between the semiconductor patterns, said gate electrode including a first inner electrode, a second inner electrode, and a third inner electrode, which extend between adjacent ones of the semiconductor patterns, and an outer electrode, which is provided on the uppermost one of the semiconductor patterns;
a gate insulating pattern on the gate electrode;
a gate capping pattern on a top surface of the outer electrode;
a first interlayer insulating layer on the source/drain patterns;
a second interlayer insulating layer on the first interlayer insulating layer and the gate capping pattern;
a third interlayer insulating layer on the second interlayer insulating layer, said third interlayer insulating layer including metal patterns and vias;
an active contact that penetrates the first and second interlayer insulating layers and electrically connects the second pattern of the source/drain pattern to the metal pattern;
a backside conductive structure that penetrates the substrate and electrically connects the first pattern to the power delivery network layer; and
a lower insulating pattern extending below the second pattern;
wherein a bottom surface of the lower insulating pattern and a bottom surface of the backside conductive structure are coplanar with each other; and
wherein a top surface of the lower insulating pattern is located at a level that is lower than or equal to a top surface of the backside conductive structure.

19. The device of claim 18, wherein the lower insulating pattern and the backside conductive structure are in direct contact with the lower interconnection line.

20. The device of claim 18, wherein the lower insulating pattern is located at a first height in a direction perpendicular to the substrate; wherein the backside conductive structure is located at a second height in the direction perpendicular to the substrate; wherein the second height is greater than the first height; and wherein the lower insulating pattern comprises at least one of silicon oxide (SiO₂), silicon nitride (SiN), aluminum oxide (Al₂O₃), or aluminum nitride (AlN).
